(19) United States
(12) Patent Application Publication
(10) Pub. No.: US 2007/0296462 A1
(43) Pub. Date: Dec. 27, 2007

(54) Logic circuit for high-side gate driver

(76) Inventors: Jong-Tae Hwang, Seoul (KR); Moon-Sang Jung, Seoul (KR); Jin-Sung Kim, Seoul (KR); Dong-Hwan Kim, Bucheon (KR)

Correspondence Address: SIDLEY AUSTIN LLP, 555 CALIFORNIA STREET, SUITE 2000, SAN FRANCISCO, CA, 94104-1715, US

(21) Appl. No.: 11/800,198

(22) Filed: May 4, 2007

(30) Foreign Application Priority Data
May 4, 2006 (KR) 10-2006-0040592

(51) Int. Cl. H03K 19/0175

(52) U.S. Cl. 326/82

(57) ABSTRACT

A logic circuit for high-side gate driver includes a p-MOSFET array connected to a first voltage source, an n-MOSFET array connected to a second voltage source, and a resistor arranged between the p-MOSFET array and the n-MOSFET array, wherein a first node between the resistor and at least one of the p-MOSFETs in the p-MOSFET array is connected to a first output terminal, and a second node between the resistor and at least one of the n-MOSFETs in the n-MOSFET array is connected to a second output terminal. An additional logic circuit can include a second p-MOSFET array, a second n-MOSFET array, and a second resistor between the second p-MOSFET array and the second n-MOSFET array, where an output signal from an output terminal between the first resistor and the first n-MOSFET array is fed back to the second p-MOSFET array and the second n-MOSFET array, and an output signal from an output terminal between the second resistor and the second n-MOSFET array is fed back to the first p-MOSFET array and the first n-MOSFET array.

### CROSS-REFERENCE TO RELATED APPLICATION

This application claims priority to and the benefit of Korea Patent Application No. 10-2006-0040592 filed on May 4, 2006 in the Korean Intellectual Property Office, the entire content of which is incorporated herein by reference.

### BACKGROUND

1. Field of the Invention

The present invention relates to a logic circuit for a high-side gate driver, and more particularly to a logic circuit for high-side gate driver capable of detecting and preventing a malfunction.

2. Description of the Related Art

FIG. 1 is a circuit diagram illustrating a conventional high-side gate driver 100. A function of the high-side gate driver 100 is to turn on/off a power switching device 200. The high-side gate driver 100 has an output terminal HO connected to a gate of the power switching device 200. Although the power switching device 200 is shown as a power MOSFET, in some circuits it may be any other suitable switching device such as an insulating gate bipolar transistor (IGBT). A DC voltage VDC of about 600V is applied to a drain of the power switching device 200. A source of the power switching device 200 is connected to a high-side floating return voltage terminal VS of the high-side gate driver 100. The high-side floating return voltage terminal VS is also connected to a cathode of a bootstrap diode DBOOT and a terminal of a bootstrap capacitor CBOOT. The other terminal of the bootstrap capacitor CBOOT is connected to the high-side floating return voltage terminal VS of the high-side gate driver 100. An anode of the bootstrap diode DBOOT is connected to a power source 200. The power source 200 is also connected to a voltage input terminal VCC of the high-side gate driver 100.

The high-side gate driver 100 includes an input detector 110 for recognizing an input signal applied to the high-side gate driver 100 through an input terminal IN, in the form of a digital signal. The high-side gate driver 100 also includes an edge pulse generator 120 for generating pulse signals, synchronized with rising and falling edges of the signal recognized by the input detector 110, respectively. The high-side gate driver 100 further includes a high-side lateral double-diffused MOS (LDMOS) circuit 130 including two LDMOSs respectively driven by the pulse signals generated from the edge pulse generator 120.

The drain of one LDMOS of the high-side LDMOS circuit 130 is connected to one end of a first resistor R1. The drain of other LDMOS of the high-side LDMOS circuit 130 is connected to one end of a second resistor R2. The sources of the LDMOSs are connected to the ground. The other ends of the first and second resistors R1 and R2 are connected to the high-side floating voltage terminal VB. When one of the LDMOSs is turned on, a voltage drop occurs in the associated first resistor R1 or second resistor R2. A voltage across the first resistor R1 or second resistor R2 is converted to a signal suitable for a logic circuit by a re-shaper 140 and is then inputted to an SR latch 150. An output from the SR latch 150 is inputted to a gate of a p-channel MOSFET M1 and an n-channel MOSFET M2 within a driver 170 via an inverter 160. In response to the inputted signal, one of the p-channel MOSFET M1 and n-channel MOSFET M2 is turned on. This is the basic outline of the operation of the power switching device 200.

In the high-side gate driver 100 having the above-mentioned configuration, a voltage for the first resistor R1, second resistor R2, re-shaper 140, SR latch 150, and driver 170 is supplied from the bootstrap capacitor CBOOT which is connected between the high-side floating voltage terminal VB and the high-side floating return voltage terminal VS, as a floating voltage source. Where the high-side gate driver 100 is ideal, its output signal HO is produced only based on an input signal IN applied to the high-side gate driver 100. However, in practical cases, the state of the output signal HO may be changed due to noise of various origins between the high-side floating voltage terminal VB and the high-side floating return voltage terminal VS. As a result, the high-voltage switching device 200 may perform undesirable operations. These may even include a malfunction, resulting in the destruction of the high-side gate driver 100 or high-side switching device 200. In particular, when the re-shaper 140 and SR latch 150 malfunctions, it adversely affects the SR latch 150. In this case, a serious problem may occur because the malfunction status may be stored to be subsequently repeated. One factor causing the malfunction of the re-shaper 140 or SR latch 150 is a high pulse noise applied between the high-side floating voltage terminal VB and the high-side floating return voltage terminal VS. Another factor can be the formation and operation of a parasitic transistor.

FIGS. 2 and 3 are circuit diagrams illustrating a malfunction of the re-shaper 140 or SR latch 150 of FIG. 1.

In FIG. 2, the logic circuit constituting the re-shaper 140 or the SR latch 150 includes an inverter circuit including an n-channel MOSFET M21 and a p-channel MOSFET M22. When high-voltage pulse noise is applied to the high-side floating voltage terminal VB connected to the p-channel MOSFET M22, the output signal OUT corresponding to the input signal IN cannot be appropriately generated. For example, in a normal state, when the input signal IN has the same voltage level as the high-side floating return voltage terminal VS, for example, a low level, the p-channel MOSFET M22 is turned on and the n-channel MOSFET M21 is turned off. In this state, accordingly, the output signal OUT has a high level. However, in the presence of noise, and in particular, when the noise has a voltage level higher than a break-down voltage level of the n-channel MOSFET M21, current flows through the n-channel MOSFET M21 because the n-channel MOSFET M21 breaks down. As a result, the output signal OUT decreases, so that it may become a low-level state. On the other hand, when the input signal IN has a high level, the p-channel MOSFET M22 should be turned off. However, current flows through the p-channel MOSFET M22 because the insulation of the p-channel MOSFET M22 is overcome by the noise signal. As a result, the output signal OUT may become a high-level state.

Referring to FIG. 3, an npn type parasitic transistor Q1 may be formed due to the source, drain and body of the n-channel MOSFET M21. Also, a resistor R1 may be present in the body of the n-channel MOSFET M21. Similarly, an pnp type parasitic transistor Q2 may be formed due to the source, drain and body of the p-channel MOSFET M22. Also, a resistor R2 may be present in the body of the p-channel MOSFET M22. Under the condition in which there are such parasitic components, unintended voltage drops may occur in the resistors R1 or R2 when a noise is present. Due to this voltage drop, the npn type parasitic transistor Q1 or pnp type parasitic transistor Q2 may operate. When the parasitic transistor operates as mentioned above, the output signal may be changed due to the operation of the parasitic transistor, instead of being determined by the input signal IN.

### SUMMARY

In one aspect, the present invention provides a logic circuit for a high-side gate driver for detecting and preventing a malfunction caused by a noise comprising: a p type MOSFET array connected to a first voltage source; an n type MOSFET array connected to a second voltage source; and a resistor arranged between the p type MOSFET array and the n type MOSFET array.

The p type MOSFET array may comprise a plurality of p type MOSFETs having a serial arrangement, a parallel arrangement, or a combination thereof. The n type MOSFET array may comprise a plurality of n type MOSFETs having a serial arrangement, a parallel arrangement, or a combination thereof.

A first node between the resistor and at least one of the p type MOSFETs in the p type MOSFET array may be connected to a first output terminal. A second node between the resistor and at least one of the n type MOSFETs in the n type MOSFET array may be connected to a second output terminal.

At least one input terminal may be connected to gates of the p type MOSFETs in the p type MOSFET array and gates of the n type MOSFETs in the n type MOSFET array.

In another aspect, the present invention provides a logic circuit comprising: a first logic circuit comprising a first p type MOSFET array receiving a voltage from a first voltage source and an input signal from a first input terminal, a first n type MOSFET array receiving a voltage from a second voltage source and the input signal from the first input terminal, and a first resistor arranged between the first p type MOSFET array and the first n type MOSFET array; and a second logic circuit comprising a second p type MOSFET array receiving the voltage from the first voltage source and an input signal from a second input terminal, a second n type MOSFET array receiving the voltage from the second voltage source and the input signal from the second input terminal, and a second resistor arranged between the second p type MOSFET array and the second n type MOSFET array, wherein an output signal from an output terminal between the first resistor and the first n type MOSFET array is fed back to the second p type MOSFET array and the second n type MOSFET array, and an output signal from an output terminal between the second resistor and the second n type MOSFET array is fed back to the first p type MOSFET array and the first n type MOSFET array.

An output signal from an output terminal between the first p type MOSFET array and the first resistor may be fed back to the second logic circuit. An output signal from an output terminal between the second p type MOSFET array and the second resistor may be fed back to the first logic circuit.

In another aspect, the present invention provides a logic circuit comprising: a first inverter comprising a first p type MOSFET receiving a voltage from a first voltage source and an input signal from a first input terminal, a first n type MOSFET receiving a voltage from a second voltage source and the input signal from the first input terminal, and a first resistor arranged between the first p type MOSFET and the first n type MOSFET; a second inverter comprising a second p type MOSFET receiving the voltage from the first voltage source and an input signal from a second input terminal, a second n type MOSFET receiving the voltage from the second voltage source and the input signal from the second input terminal, and a second resistor arranged between the second p type MOSFET and the second n type MOSFET; a first logic circuit comprising a first p type MOSFET array receiving the voltage from the first voltage source and an input signal from the first inverter, a first n type MOSFET array receiving the voltage from the second voltage source and the input signal from the first inverter, and a third resistor arranged between the first p type MOSFET array and the first n type MOSFET array; and a second logic circuit comprising a second p type MOSFET array receiving the voltage from the first voltage source and an input signal from the second inverter, a second n type MOSFET array receiving the voltage from the second voltage source and the input signal from the second inverter, and a fourth resistor arranged between the second p type MOSFET array and the second n type MOSFET array, wherein an output signal from an output terminal between the first resistor and the first n type MOSFET array is fed back to the second p type MOSFET array and the second n type MOSFET array, and an output signal from an output terminal between the second resistor and the second n type MOSFET array is fed back to the first p type MOSFET array and the first n type MOSFET array.

An output signal from an output terminal between the first p type MOSFET array and the first resistor may be fed back to the second logic circuit. An output signal from an output terminal between the second p type MOSFET array and the second resistor may be fed back to the first logic circuit.

The first p type MOSFET array and the first n type MOSFET array may receive a signal output from an output terminal between the first p type MOSFET and the first resistor, as the input signal from the first inverter. The second p type MOSFET array and the second n type MOSFET array may receive a signal output from an output terminal between the second p type MOSFET and the second resistor, as the input signal from the second inverter.

### BRIEF DESCRIPTION OF THE DRAWINGS

FIG. 1 is a circuit diagram illustrating a conventional high-side gate driver.

FIGS. 2 and 3 are circuit diagrams illustrating a malfunction of a re-shaper or SR latch shown in FIG. 1.

FIG. 4 is a circuit diagram illustrating a logic circuit for a high-side gate driver according to an embodiment of the invention.

FIGS. 5 and 6 are circuit diagrams illustrating an operation for sensing a malfunction of the logic circuit shown in FIG. 4.

FIG. 7 is a circuit diagram illustrating a logic circuit for a high-side gate driver according to another embodiment of the invention.

FIG. 8 is a circuit diagram illustrating an embodiment of a mono-stable circuit using the logic circuit of FIG. 7.

FIG. 9 is a circuit diagram illustrating another embodiment of a mono-stable circuit using the logic circuit of FIG. 7.

FIG. 10 is a circuit diagram illustrating an SR latch circuit using the inverter of FIG. 4 and the mono-stable circuit of FIG. 9.

FIG. 11 is an equivalent circuit diagram of the SR latch circuit shown in FIG. 10.

FIGS. 12 and 13 are graphs for comparing the case using the logic circuit according to the present invention with the conventional case in terms of the influence of a noise signal.

FIG. 14 is a graph depicting a waveform of a malfunction caused by negative pulses when the conventional logic circuit is used.

FIGS. 15 and 16 are graphs depicting a waveform of a malfunction caused by negative pulses when the logic circuit according to the invention is used.

### DETAILED DESCRIPTION

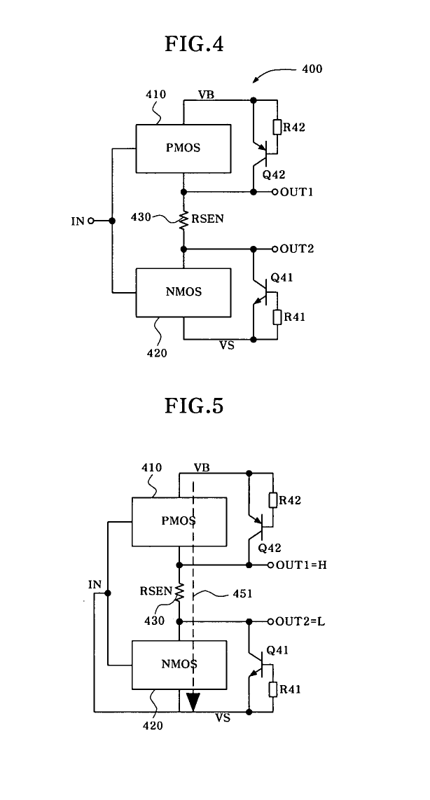

FIG. 4 is a circuit diagram illustrating a logic circuit 400 for a high-side gate driver according to an embodiment of the present invention. The logic circuit 400 may include a p type MOSFET (PMOS) 410 connected to a first voltage source, such as a high-side floating voltage terminal VB; an n type MOSFET (NMOS) 420 connected to a second voltage source, such as a high-side floating return voltage terminal VS, and a resistor (RSEN) 430, which can be arranged between the p type MOSFET 410 and the n type MOSFET 420. In FIG. 4, transistors Q41 and Q42 and resistors R41 and R42 can be parasitic components. In some cases, in place of the p type MOSFET 410, a p type MOSFET array may be used, which can include a plurality of p type MOSFETs having a serial arrangement, a parallel arrangement, or a combination thereof. Similarly, in place of the n type MOSFET 420, an n type MOSFET array may be used, which can include a plurality of n type MOSFETs having a serial arrangement, a parallel arrangement, or a combination thereof.

The p type MOSFET 410 and n type MOSFET 420 can be connected in common to a common input terminal IN. The logic unit can include two output terminals. A first output terminal OUT1 can be arranged between the p type MOSFET 410 and the resistor 430. A second output terminal OUT2 can be arranged between the n type MOSFET 420 and the resistor 430. When a high-level signal is input to the input terminal IN as an input signal, the p type MOSFET 410 can be turned off and the n type MOSFET 420 can be turned on. First and second output signals, which are output at the first and second output terminals OUT1 and OUT2, respectively, can have the same voltage level, for example, a low level, unless a malfunction occurs. On the other hand, when the input signal applied to the input terminal IN has a low level, the p type MOSFET 410 can be turned on and the n type MOSFET 420 can be turned off. In this case, the first and second output signals respectively output at the first and second output terminals OUT1 and OUT2 can have the same level, for example, a high level, unless a malfunction occurs. In contrast, in either case, the first and second output signals will have different levels if a malfunction occurs. Accordingly, it is possible to determine the malfunction of the circuit by sensing the fact that the first and second output signals are different from each other.

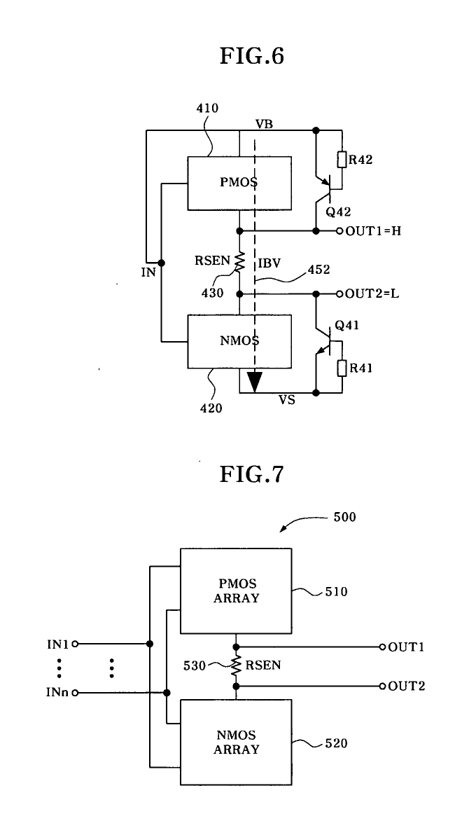

FIGS. 5 and 6 are circuit diagrams illustrating an operation for sensing a malfunction of the logic circuit shown in FIG. 4. In FIGS. 5 and 6, reference numerals identical to those of FIG. 4 designate constituent elements analogous or identical to those of FIG. 4. Referring to FIG. 5, the input terminal IN can be short-circuited with the high-side floating return terminal VS. In this case, a low-level signal is input to the input terminal IN. In this case, the p type MOSFET 410 is turned on and the n type MOSFET 420 is turned off. In the course of normal operations, no current flows through the resistor 430 in this case. As a result, high-level output signals are output at the first and output terminals OUT1 and OUT2. However, when the n type MOSFET 420 breaks down, or a parasitic transistor is turned on due to pulse noise, as described above, current can flow through the resistor 430, as indicated by an arrow 451 in FIG. 5, so that voltage drop occurs across the resistor 430. As a result, a high-level output signal can be output at the first output terminal OUT1 and a low-level output signal is output at the second output terminal OUT2. Based on the different levels of the output signals output at the first and second output terminals OUT1 and OUT2, it can be determined that the inverter malfunctions.

Referring to FIG. 6, the input terminal IN can be short-circuited with the high-side floating terminal VB. In this case, a high-level signal is input to the input terminal IN. In this case, the p type MOSFET 410 can be turned off, and the n type MOSFET 420 can be turned on. In a normal state, accordingly, no current flows through the resistor 430. As a result low-level signals are output at the first and output terminals OUT1 and OUT2, as output signals, respectively. However, when the p type MOSFET 410 breaks down, or a parasitic transistor is turned on due to pulse noise, as described above, current can flow through the resistor 430, as indicated by an arrow 452 in FIG. 6. As a result, a high-level output signal is output at the first output terminal OUT1, and a low-level output signal is output at the second output terminal OUT2. In this case, it can also be determined that the inverter malfunctions, based on the different levels of the output signals output at the first and second output terminals OUT1 and OUT2.

FIG. 7 is a circuit diagram illustrating a logic circuit 500 for a high-side gate driver. The logic circuit 500 can include a p type MOSFET array 510, an n type MOSFET array 520, and a resistor (RSEN) 530. The p type MOSFET array 510 may include a plurality of p type MOSFETs having a serial arrangement, a parallel arrangement, or a combination thereof. Similarly, the n type MOSFET array 520 may include a plurality of n type MOSFETs having a serial arrangement, a parallel arrangement, or a combination thereof. A plurality of input terminals IN1, . . . , INn can be connected to each of the p type MOSFET array 510 and n type MOSFET array 520. Although in the present embodiment the number of the input terminals IN1, . . . , INn is the same as the number of the p type MOSFETs in the p type MOSFET array 510 and the number of the n type MOSFETs in the n type MOSFET array 520, these numbers may be different in other embodiments. In this embodiment, a first output terminal OUT1 and a second output terminal OUT2 are arranged at the opposite ends of the resistor 530, similarly to the first embodiment. Accordingly, it is possible to determine whether or not the logic circuit malfunctions, based on whether the first and second output signals output at the first and second output terminals OUT1 and OUT2, respectively, are identical to or different from each other.

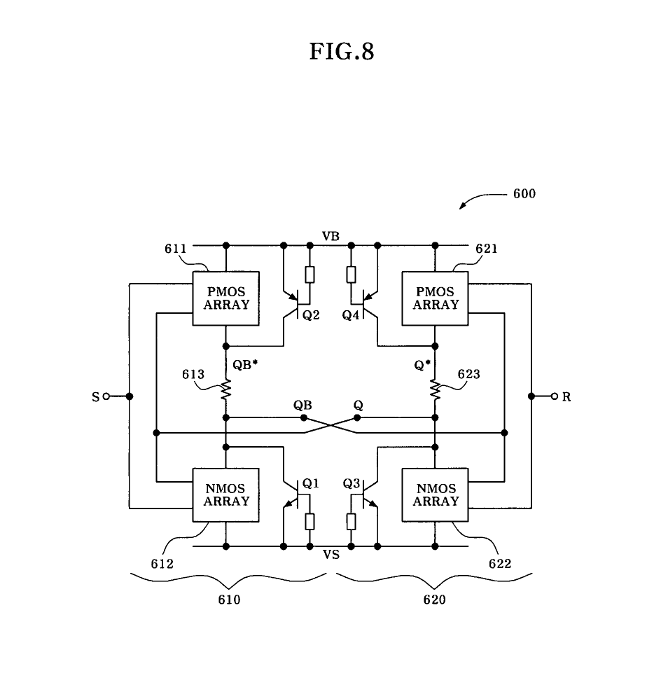

FIG. 8 is a circuit diagram illustrating an embodiment of a mono-stable circuit 600 using the logic circuit of FIG. 7. Referring to FIG. 8, a first logic circuit 610 and a second logic circuit 620 can be arranged in parallel. In this embodiment, the first and second logic circuits 610 and 620 have a NAND type structure. That is, when each of the two input signals has a high level, the n type MOSFET array is turned on. The first logic circuit can include a first p type MOSFET array 611, a first n type MOSFET array 612, and a first resistor 613 arranged between the first p type MOSFET array 611 and the first n type MOSFET array 612. These constituent elements can have the same configurations as those of FIG. 7. Similarly, the second logic circuit can include a second p type MOSFET array 621, a second n type MOSFET array 622, and a second resistor 623 arranged between the second p type MOSFET array 621 and the second n type MOSFET array 622. In FIG. 8, transistors Q1, Q2, Q3, and Q4 can be parasitic transistors.

The first and second p type MOSFET arrays 611 and 621 can be connected to the first voltage source, which can be the high-side floating voltage terminal VB. The first and second n type MOSFET arrays 612 and 622 can be connected to the second voltage source, which can be the high-side floating return voltage terminal VS. The first p type MOSFET array 611 and first n type MOSFET array 612 can receive an input signal from a first input terminal S. The second p type MOSFET array 621 and second n type MOSFET array 622 can receive an input signal from a second input terminal R.

The first logic circuit 610 can include two output terminals QB and QB* respectively arranged at opposite ends of the first resistor 613. The second logic circuit 620 can include two output terminals Q and Q* respectively arranged at opposite ends of the second resistor 623. The output terminal QB arranged between the first resistor 613 and the first n type MOSFET array 612 in the first logic circuit 610 is connected to the second p type MOSFET array 621 and second n type MOSFET array 622 in the second logic circuit 620, to feed back the output signal from the output terminal QB. Similarly, the output terminal Q arranged between the second resistor 623 and the second n type MOSFET array 622 in the second logic circuit 620 is connected to the first p type MOSFET array 611 and first n type MOSFET array 612 in the first logic circuit 610, to feed back the output signal from the output terminal Q. In accordance with such a positive feedback structure, the mono-stable circuit 600 of FIG. 8 may be used as a memory circuit for storing the status of an output signal. In such a mono-stable circuit, similarly to the above-described cases, it is possible to determine whether or not the first inverter malfunctions, by comparing signals output from the output terminals QB and QB* arranged at the opposite ends of the first resistor 613 of the first logic circuit 610. Similarly, it is also possible to determine whether or not the second inverter malfunctions, by comparing signals output from the output terminals Q and Q* arranged at the opposite ends of the second resistor 623 of the second logic circuit 620.

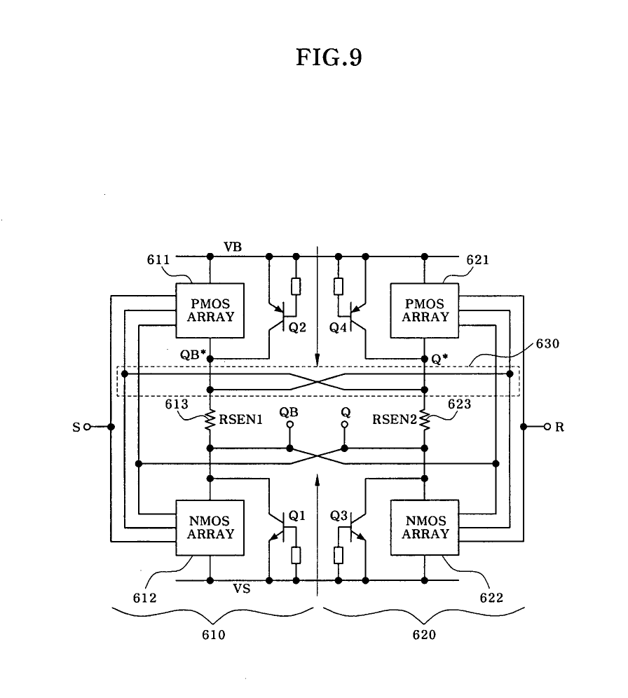

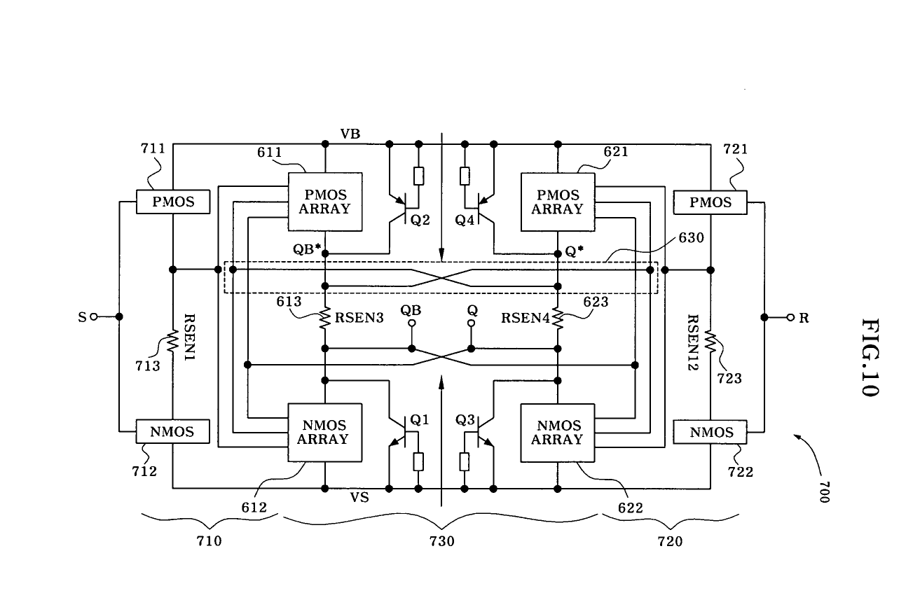

FIG. 9 is a circuit diagram illustrating another embodiment of a mono-stable circuit 601 using the logic circuit of FIG. 7. In FIG. 9, reference numerals identical to those of FIG. 8 designate elements analogous to those of FIG. 8. Referring to FIG. 9, the mono-stable circuit 601 can have a configuration capable of sensing a malfunction of the logic circuits. The mono-stable circuit 601 can, even when the logic circuits malfunction, can prevent the output status of the mono-stable circuit from being changed due to the malfunction of the logic circuits. In detail, the signal output from the output terminal QB* arranged between the first p type MOSFET array 611 and the first resistor 613 in the first logic circuit 610 is fed back such that it is input to the second logic circuit 620, as indicated by a block 630 in FIG. 9. Similarly, the signal output from the output terminal Q* arranged between the second p type MOSFET array 621 and the second resistor 623 in the second logic circuit 620 is fed back such that it is input to the first logic circuit 610.

Hereinafter, a malfunction preventing operation of the above-described mono-stable circuit 601 will be described in detail. When a malfunction occurs, a voltage drop occurs across at least one of the first and second resistors 613 and 623. That is, in certain cases the voltage levels of the signals output at the output terminals QB and QB* of the first inverter become different from each other. Otherwise, the voltage levels of the signals output at the output terminals Q and Q* of the second inverter become different from each other.

Accordingly, it is possible to make it less likely that the status of the mono-stable circuit changes as a consequence of a break-down of MOSFETs induced by noise, or a malfunction induced by parasitic devices, by turning on the first p type MOSFET array 611 only when both output signals from the output terminals Q and Q* of the second logic circuit 620 have a low level, and turning on the second n type MOSFET array 622 only when both output signals from the output terminals QB and QB* of the first logic circuit 610 have a low level.

In embodiments, where the logic circuits are NOR type, it is possible to suppress the likelihood of the status of the mono-stable circuit changing, caused by a break-down of MOSFETs induced by noise, or a malfunction induced by parasitic devices, by turning on the first n type MOSFET array 612 only when both output signals from the output terminals Q and Q* of the second logic circuit 620 have a high level, and turning on the second p type MOSFET array 621 only when both output signals from the output terminals QB and QB* of the first logic circuit 610 have a high level.

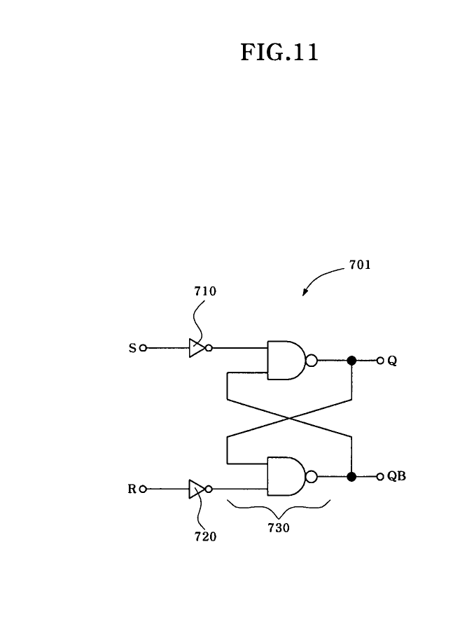

FIG. 10 is a circuit diagram illustrating an SR latch 700 using the logic circuit 400 of FIG. 4 and the mono-stable circuit 601 of FIG. 9. FIG. 11 is an equivalent circuit diagram 701 of the SR latch 700 shown in FIG. 10. Referring to FIGS. 10 and 11, the SR latch 700 can include a first inverter 710, a second inverter 720, and a mono-stable circuit 730 arranged between the first and second inverters 710 and 720. The first inverter 710 can include a first p type MOSFET (PMOS) 711 connected to a high-side floating voltage terminal VB, a first n type MOSFET (NMOS) 712 connected to a high-side floating return voltage terminal VS, and a resistor (RSEN1) 713 arranged between the first p type MOSFET 711 and the first n type MOSFET 712. The second inverter 720 can include a second p type MOSFET (PMOS) 721 connected to the high-side floating voltage terminal VB, a second n type MOSFET (NMOS) 722 connected to the high-side floating return voltage terminal VS, and a resistor (RSEN2) 723 arranged between the second p type MOSFET 721 and the second n type MOSFET 722. The first p type MOSFET 711 and first n type MOSFET 712 can receive an input signal from a first input terminal S. The second p type MOSFET 721 and second n type MOSFET 722 can receive an input signal from the second input terminal R. The outputs from the first and second inverters 710 and 720 can be used as an input for the mono-stable circuit 730. The first inverter 710 can have an output terminal arranged between the first p type MOSFET 711 and the first resistor 723. The second inverter 720 can have an output terminal arranged between the second p type MOSFET 721 and the second resistor 723. The configurations of the first and second inverters 710 and 720 can be analogous to the logic circuit 400 of FIG. 4. Also, the configuration of the mono-stable circuit 730 can be analogous to mono-stable circuit 600 of FIG. 9. Accordingly, no detailed description will be given of the detailed circuit configuration of the mono-stable circuit 730.

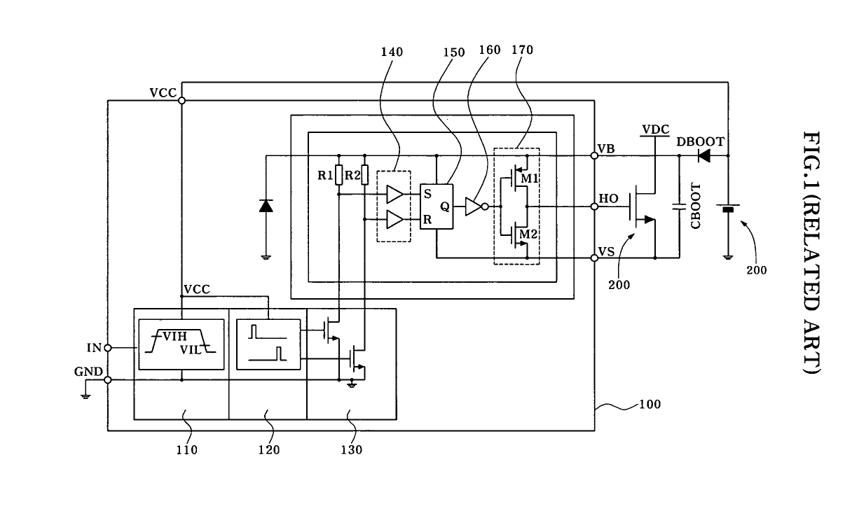

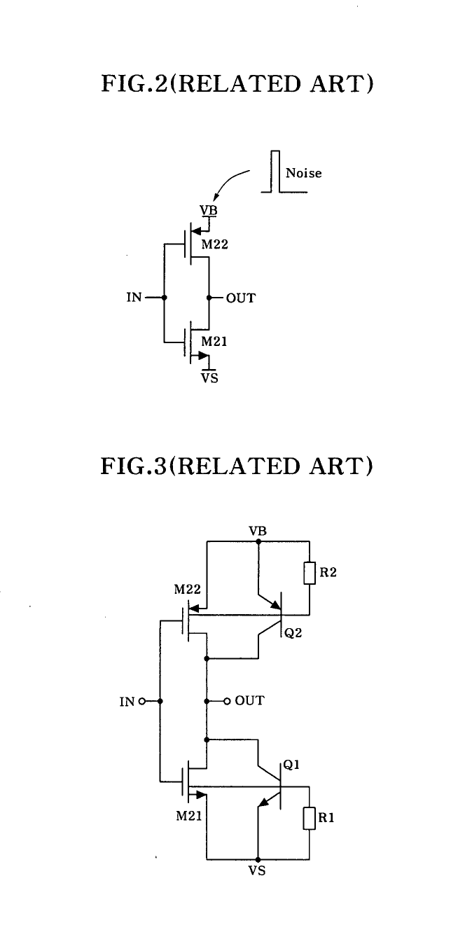

In the SR latch 700, the first p type MOSFET array 611 can be turned on only when both the output signals from the output terminals QB and QB* of the resistor (RSEN4) 623, arranged between the second p type MOSFET array 621 and the second n type MOSFET array 622, have a low level. The second n type MOSFET array 622 is turned on only when both the output signals from the output terminals Q and Q* of the resistor (RSEN3) 613 arranged between the first p type MOSFET array 611 and the first n type MOSFET array 612 have a low level. The input signals at the first and second input terminals S and R of the SR latch circuit can be maintained at a low level for most periods because only the edge information of each input signal is input to the high-side gate driver, as described above with reference to FIG. 1. When the input signals at the first and second input terminals S and R are maintained at a low level, the outputs from the first and second inverters 710 and 720 are maintained at a high level. When a noise is input in the SR latch circuit, generated by the high-side floating voltage terminal VB, a control operation can be performed to enable the output signal from the output terminal between the first p type MOSFET 711 and the first resistor 713 to be input to the mono-stable circuit 730 because the state of the mono-stable circuit 730 does not change only when the outputs of the first and second inverters 710 and 720 are maintained at a high level. Similarly, a control operation can be also performed to enable the output signal from the output terminal between the second p type MOSFET 721 and the second resistor 723 to be input to the mono-stable circuit 730. Thus, the outputs of the first and second inverters 710 and 720 are maintained at a high level only when an input signal other than a noise signal is input to the first and second inverters 710 and 720. In a malfunction state caused by a noise signal, the outputs of the first and second inverters 710 and 720 are maintained at a low level. The operation of the mono-stable circuit 730 is analogous to the operation described with reference to FIG. 9.

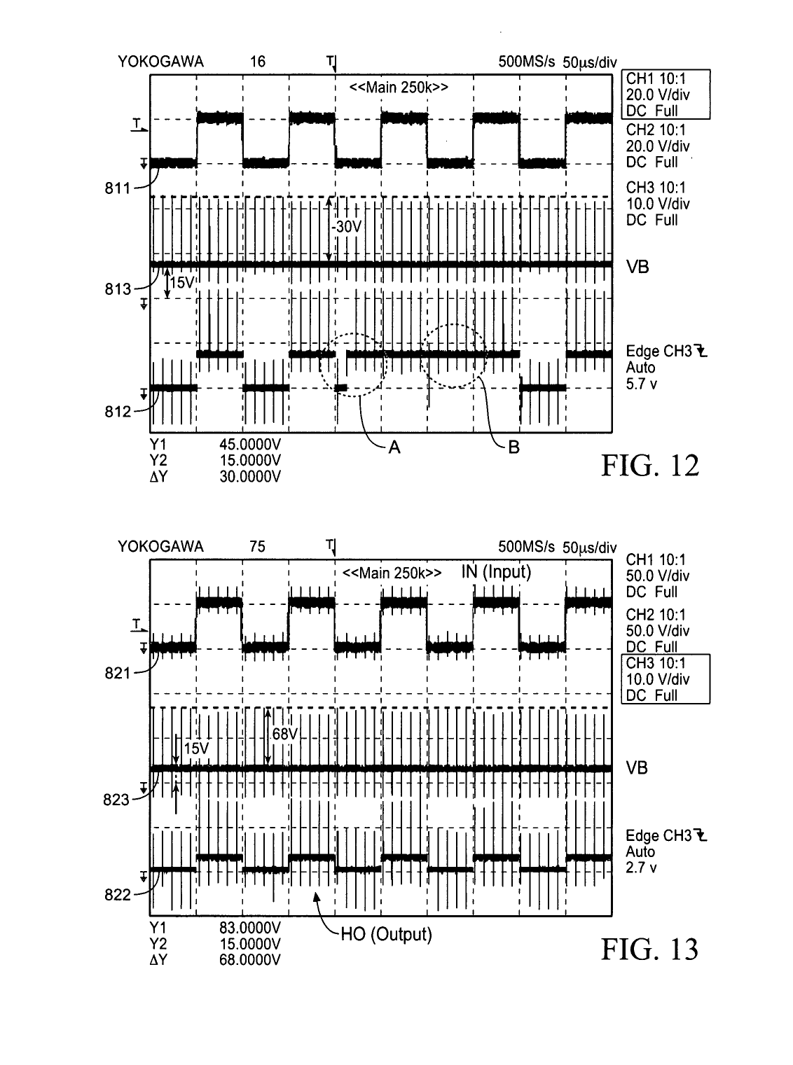

FIGS. 12 and 13 compare waveforms of the above embodiments and conventional systems, illustrating the influence of noise. FIG. 12 illustrates the waveforms of the conventional systems when a noise signal 813 with a pulse peak of about 30V is applied to the high-side floating voltage terminal VB. In this case, when a square wave is input as an input signal IN 811, a malfunction occurs because the generated output signal HO 812 does not correspond to the input signal IN 811. This is particularly clear at the A and B segments of the output waveforms.

FIG. 13, on the other hand, illustrates that in some embodiments of the present invention even when a noise signal 823 with a pulse peak of about 66V is applied to the high-side floating voltage terminal VB, no malfunction occurs when a square wave is input as an input signal IN 821, since the generated output signal HO 822 does correspond to the input signal IN 821.

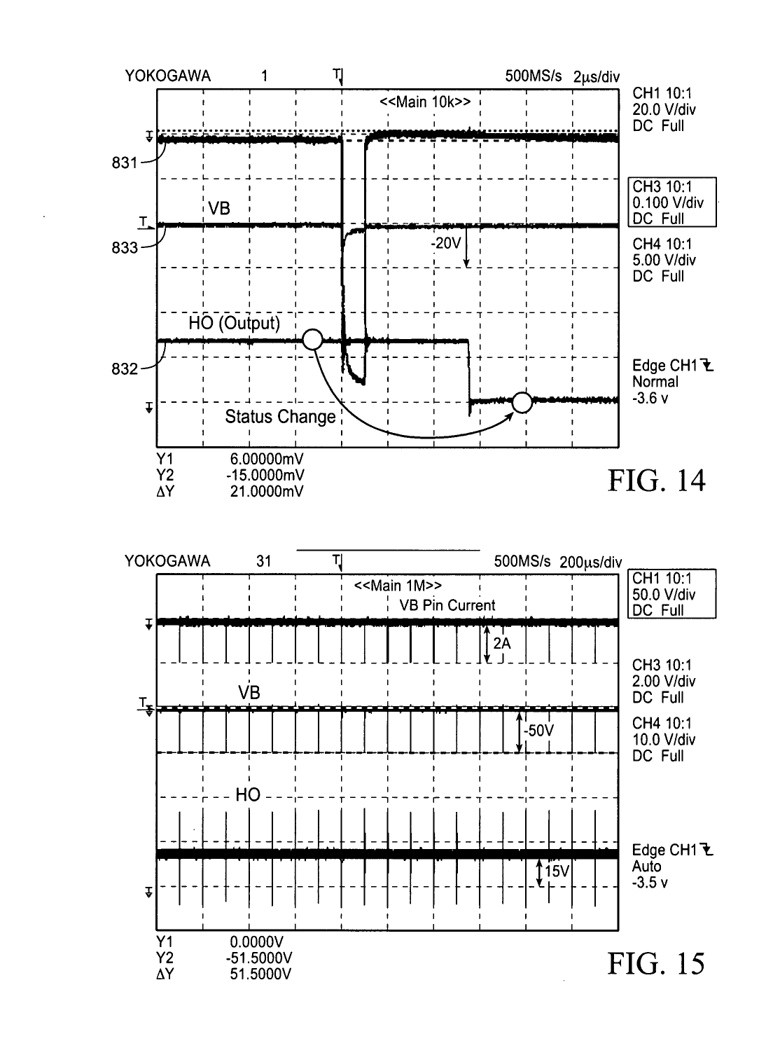

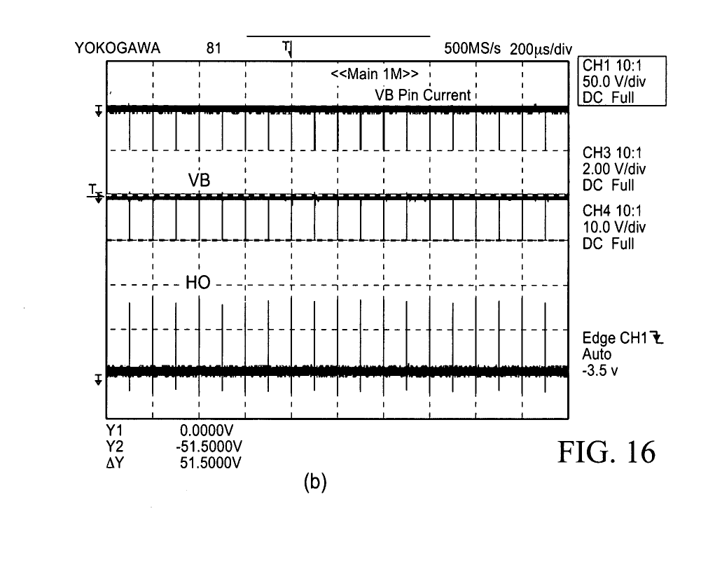

FIG. 14 is a graph depicting a waveform of a malfunction caused by negative pulses in conventional logic circuits. FIGS. 15 and 16 are graphs depicting a waveform of a malfunction caused by negative pulses in some embodiments of the present invention. FIG. 14 illustrates that in a conventional logic circuit, an output 832 from an SR latch circuit is changed from a high level to a low level, as indicated by an arrow in FIG. 14, when a signal 833 applied to the high-side floating voltage terminal VB transitions from a negative state to a positive state. The signals, which are caused by the VS pulse noise, correspond to a malfunction. In this case, the voltage at the high-side floating voltage terminal VB has been recovered to 0V after being dropped to 10V by a pin current. Pin currents refer to currents drawn from the corresponding pins.

FIGS. 15 and 16 illustrate that, even when a peak pulse 843 of about −50V is applied to the high-side floating voltage terminal VB using a pin current 841, after changing an output signal 842 to a high/low level, an original output status is maintained irrespective of the noise signal applied to the high-side floating voltage terminal VB. Here the original output status corresponds to the state of the monostable circuit.

As apparent from the above description, in embodiments of an inverter for a high-side gate driver and a logic circuit using the inverter, there is an advantage in that it is possible to accurately determine whether or not a malfunction occurred due to a noise signal causing a break-down of a MOSFET or turn-on of a parasitic transistor, and to prevent the malfunction caused by the noise signal by an appropriate feedback control.

Although embodiments of the invention have been disclosed for illustrative purposes, those skilled in the art will appreciate that various modifications, additions and substitutions are possible, without departing from the scope and spirit of the invention, which is only defined by the accompanying claims.

What is claimed is:

1. A logic circuit for a high-side gate driver comprising:
a p-type MOSFET array connected to a first voltage source;
an n-type MOSFET array connected to a second voltage source; and
a resistor arranged between the p type MOSFET array and the n type MOSFET array, wherein
a first node between the resistor and at least one of the p type MOSFETs in the p type MOSFET array is connected to a first output terminal, and a second node between the resistor and at least one of the n type MOSFETs in the n type MOSFET array is connected to a second output terminal.

2. The logic circuit according to claim 1, wherein the p type MOSFET array comprises a plurality of p type MOSFETs having a serial arrangement, a parallel arrangement, or a combination thereof, and the n type MOSFET array comprises a plurality of n type MOSFETs having a serial arrangement, a parallel arrangement, or a combination thereof.

3. The logic circuit according to claim 2, wherein at least one input terminal is connected to gates of the p type MOSFETs in the p type MOSFET array and gates of the n type MOSFETs in the n type MOSFET array.

4. A logic circuit comprising:
a first logic circuit comprising a first p type MOSFET array receiving a voltage from a first voltage source and an input signal from a first input terminal, a first n type MOSFET array receiving a voltage from a second voltage source and the input signal from the first input terminal, and a first resistor arranged between the first p type MOSFET array and the first n type MOSFET array; and
a second logic circuit comprising a second p type MOSFET array receiving the voltage from the first voltage source and an input signal from a second input terminal, a second n type MOSFET array receiving the voltage from the second voltage source and the input signal from the second input terminal, and a second resistor arranged between the second p type MOSFET array and the second n type MOSFET array,
wherein an output signal from an output terminal between the first resistor and the first n type MOSFET array is fed back to the second p type MOSFET array and the second n type MOSFET array, and an output signal from an output terminal between the second resistor and the second n type MOSFET array is fed back to the first p type MOSFET array and the first n type MOSFET array.

5. The logic circuit according to claim 4, wherein an output signal from an output terminal between the first p type MOSFET array and the first resistor is fed back to the second logic circuit, and an output signal from an output terminal between the second p type MOSFET array and the second resistor is fed back to the first logic circuit.

6. A logic circuit comprising:
a first inverter comprising a first p type MOSFET receiving a voltage from a first voltage source and an input signal from a first input terminal, a first n type MOSFET receiving a voltage from a second voltage source and the input signal from the first input terminal, and a first resistor arranged between the first p type MOSFET and the first n type MOSFET;
a second inverter comprising a second p type MOSFET receiving the voltage from the first voltage source and an input signal from a second input terminal, a second n type MOSFET receiving the voltage from the second voltage source and the input signal from the second input terminal, and a second resistor arranged between the second p type MOSFET and the second n type MOSFET;
a first logic circuit comprising a first p type MOSFET array receiving the voltage from the first voltage source and an input signal from the first inverter, a first n type MOSFET array receiving the voltage from the second voltage source and the input signal from the first inverter, and a third resistor arranged between the first p type MOSFET array and the first n type MOSFET array; and
a second logic circuit comprising a second p type MOSFET array receiving the voltage from the first voltage source and an input signal from the second inverter, a second n type MOSFET array receiving the voltage from the second voltage source and the input signal from the second inverter, and a fourth resistor arranged between the second p type MOSFET array and the second n type MOSFET array,
wherein an output signal from an output terminal between the first resistor and the first n type MOSFET array is fed back to the second p type MOSFET array and the second n type MOSFET array, and an output signal from an output terminal between the second resistor and the second n type MOSFET array is fed back to the first p type MOSFET array and the first n type MOSFET array.

7. The logic circuit according to claim 6, wherein an output signal from an output terminal between the first p type MOSFET array and the first resistor is fed back to the second logic circuit, and an output signal from an output terminal between the second p type MOSFET array and the second resistor is fed back to the first logic circuit.

8. The logic circuit according to claim 6, wherein the first p type MOSFET array and the first n type MOSFET array receive a signal output from an output terminal between the first p type MOSFET and the first resistor, as the input signal from the first inverter, and the second p type MOSFET array and the second n type MOSFET array receive a signal output from an output terminal between the second p type MOSFET and the second resistor, as the input signal from the second inverter.
